(19) United States
(12) Patent Application Publication
(10) Pub. No.: US 2025/0087454 A1
(43) Pub. Date: Mar. 13, 2025

(54) ETCHING METHOD AND PLASMA PROCESSING APPARATUS

(71) Applicant: Tokyo Electron Limited, Tokyo (JP)

(72) Inventors: Sho KUMAKURA, Miyagi (JP); Soichiro KIMURA, Miyagi (JP); Koyumi SASA, Miyagi (JP); Nobuhiro ODASHIMA, Miyagi (JP); Yuji MASAKI, Miyagi (JP); Noboru TAKEMOTO, Miyagi (JP); Makoto KOBAYASHI, Miyagi (JP)

(73) Assignee: Tokyo Electron Limited, Tokyo (JP)

(21) Appl. No.: 18/955,997

(22) Filed: Nov. 22, 2024

Related U.S. Application Data
(63) Continuation of application No. PCT/JP2022/023499, filed on Jun. 10, 2022.
(60) Provisional application No. 63/365,656, filed on Jun. 1, 2022.

(51) Int. Cl. H01J 37/305; H01L 21/02

(52) U.S. Cl. CPC H01J 37/3056; H01L 21/02274; H01J 2237/3341

(57) ABSTRACT

An etching method includes: (a) providing a substrate, the substrate including a first film and a second film having openings on the first film, the first film containing a metallic element and a non-metallic element, and (b) etching the first film through the openings. The (b) includes: (i) etching the first film through the openings with a first plasma generated from a first processing gas including a halogen-containing gas by supplying a pulse of a radio-frequency power, (ii) modifying a sidewall of a recess formed in the (i) with a second plasma generated from a second processing gas, and (iii) repeating the (i) and the (ii).

### CROSS-REFERENCE TO RELATED APPLICATIONS

This application is a bypass continuation application of international application No. PCT/JP2022/023499 having an international filing date of Jun. 10, 2022, and designating the United States, the international application being based upon and claiming the benefit of priority from U.S. Provisional Application No. 63/365,656, filed on Jun. 1, 2022, the entire contents of each are incorporated herein by reference.

### TECHNICAL FIELD

Exemplary embodiments of the present disclosure relate to an etching method and a plasma processing apparatus.

### BACKGROUND

In the manufacture of an electronic device, plasma etching may be performed on a film to form a recess in the film. For the formation of such a recess, a mask is formed on the etching target film. As the mask, a resist mask is known. The resist mask is consumed during the plasma etching of the etching target film. Therefore, a hard mask has been used. As the hard mask, as described in JP2007-294836A, a hard mask formed of tungsten silicide (WSi) is known.

### CITATION LIST

### Patent Documents

Patent Document 1: JP2007-294836A

### SUMMARY

The present disclosure provides a technique of etching a film while suppressing a shape abnormality.

In one exemplary embodiment, an etching method including:
(a) a step of providing a substrate, the substrate including a first film and a second film having openings on the first film, the first film containing a metallic element and a non-metallic element, and
(b) a step of etching the first film through the openings, in which
the step (b) includes:
   (i) a step of etching the first film through the openings with a first plasma generated from a first processing gas including a halogen-containing gas by supplying a pulse of a radio-frequency power,
   (ii) a step of modifying a sidewall of a recess formed in the step (i) with a second plasma generated from a second processing gas, and
   (iii) a step of repeating the step (i) and the step (ii).

According to one exemplary embodiment, a technique of etching a film while suppressing a shape abnormality is provided.

### BRIEF DESCRIPTION OF DRAWINGS

FIG. 1 is a diagram schematically showing a plasma processing apparatus according to an exemplary embodiment.

FIG. 2 is a diagram schematically illustrating a plasma processing apparatus according to an exemplary embodiment.

FIG. 3 is a flowchart of an etching method according to one exemplary embodiment.

FIG. 4 is a cross-sectional view of an example of a substrate to which the method of FIG. 3 may be applied.

FIG. 5 is a cross-sectional view illustrating a step in the etching method according to one exemplary embodiment.

FIG. 6 is a cross-sectional view illustrating a step in the etching method according to one exemplary embodiment.

FIG. 7 is a cross-sectional view illustrating a step in the etching method according to one exemplary embodiment.

FIG. 8 is a cross-sectional view illustrating a step in the etching method according to one exemplary embodiment.

FIG. 9 is a cross-sectional view illustrating a step in the etching method according to one exemplary embodiment.

FIG. 10 is an example of a timing chart illustrating the temporal changes of a source power and a bias power.

FIG. 11 is an example of a timing chart illustrating the temporal changes of the source power and the bias power.

FIG. 12 is an example of a timing chart illustrating the temporal changes of the source power and the bias power.

FIG. 13 is an example of a timing chart illustrating the temporal changes of the source power and the bias power.

FIG. 14 is a flowchart of an etching method according to one exemplary embodiment.

FIG. 15 is a cross-sectional view illustrating a step in the etching method according to one exemplary embodiment.

FIG. 16 is a cross-sectional view illustrating a step in the etching method according to one exemplary embodiment.

FIG. 17 is a cross-sectional view illustrating a step in the etching method according to one exemplary embodiment.

FIG. 18 is a cross-sectional view illustrating a step in the etching method according to one exemplary embodiment.

FIG. 19 shows a substrate processing system according to one exemplary embodiment.

### DETAILED DESCRIPTION

Hereinafter, various exemplary embodiments will be described in detail with reference to the drawings. Further, like reference numerals will be given to like or corresponding parts throughout the drawings.

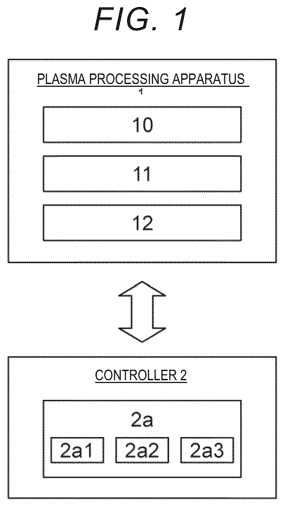

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave-excited plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2al may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2al may be a Central Processing Unit (CPU). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. The storage unit 2a2 may include a random access memory (RAM), a read only memory (ROM), a hard disk drive (HDD), a solid state drive (SSD), or a combination thereof. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC. The communication interface 2a3 may communicate with the plasma processing apparatus 1 via a communication line such as a local area network (LAN).

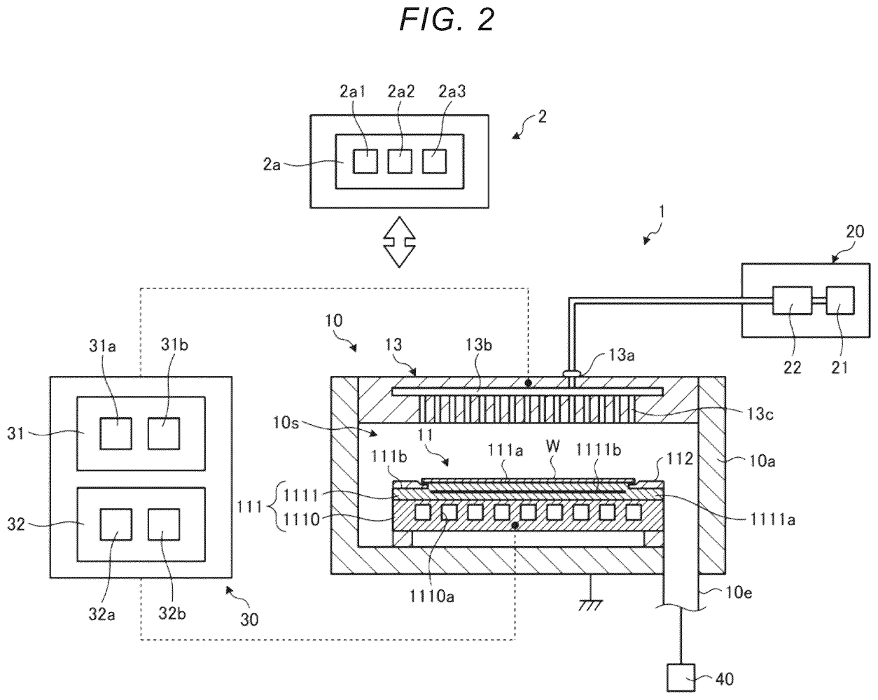

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power source 31 and/or a DC power source 32 to be described later may be disposed in the ceramic member 1111a. In this case, at least one RF/DC electrode functions as the lower electrode. In a case where a bias RF signal and/or a DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (e.g., RF power) to at least one lower electrode and/or at least one upper electrode. As a result, plasma is formed from at least one processing gas supplied into the plasma processing space 10s. Accordingly, the RF power source 31 may function as at least a part of the plasma generator 12. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (e.g., source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (e.g., bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include the DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

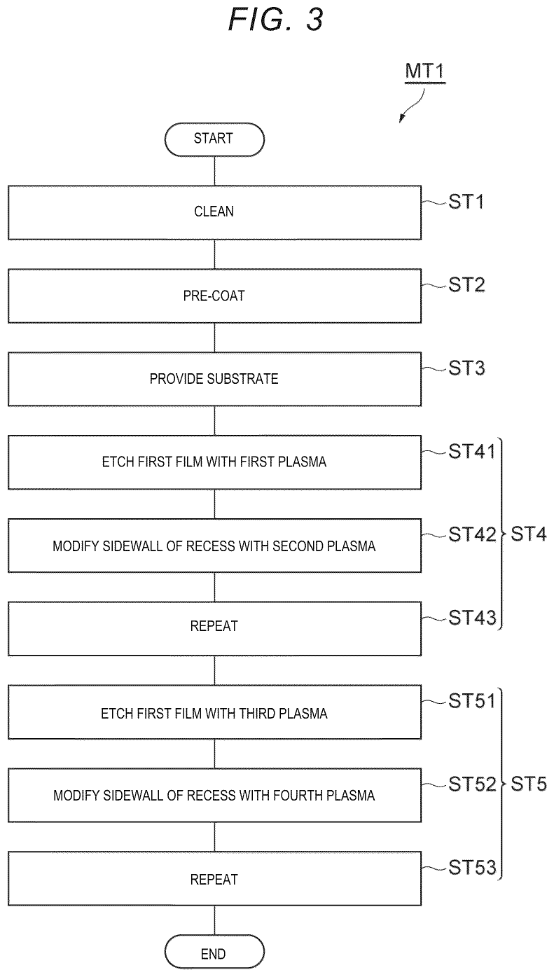

FIG. 3 is a flowchart of an etching method according to one exemplary embodiment. An etching method MT1 illustrated in FIG. 3 (hereinafter referred to as a “method MT1”) may be performed by the plasma processing apparatus 1 of the embodiment. The method MT1 may be applied to the substrate W.

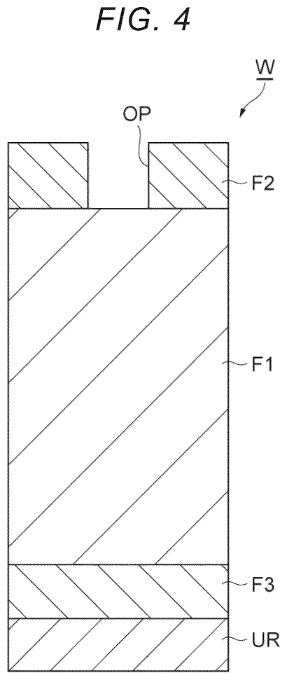

FIG. 4 is a cross-sectional view of an example of a substrate to which the method of FIG. 3 may be applied. As shown in FIG. 4, in one embodiment, the substrate W includes a first film F1 and a second film F2 on the first film F1. The substrate W may further include a third film F3 below the first film F1. The substrate W may further include an underlayer region UR below the third film F3.

The first film F1 contains a metallic element and a non-metallic element. The first film F1 may contain at least one transition metallic element selected from the group consisting of tungsten, titanium, molybdenum, hafnium, zirconium, and ruthenium as the metallic element. The first film F1 may contain at least one of silicon, carbon, nitrogen, oxygen, hydrogen, boron, or phosphorus as the non-metallic element. The first film F1 may contain at least one tungsten compound selected from the group consisting of tungsten silicide (WₓSi_{y}), tungsten silicon nitride (WₓSi_{y}N_{z}), tungsten silicon boron (WₓSi_{y}B_{z}), and tungsten silicon carbon (WₓSi_{y}C_{z}). Each of the composition ratios x, y, and z may be a real number larger than 0. The first film F1 may be a film for forming a hard mask.

The second film F2 has an opening OP. The second film F2 may have a plurality of openings OP. The opening OP may have a hole pattern or a line pattern. The dimension (CD) of the opening OP may be 30 nm or less. The second film F2 may be a mask. The second film F2 may be a silicon-containing film or a silicon oxide film. The second film F2 may be a resist mask. The second film F2 may be a photoresist mask containing tin. The second film F2 may be a resist mask for EUV exposure. The second film F2 may have a sparse pattern. The second film F2 may have a plurality of first openings OP arranged at a first pitch and having first dimensions, and a plurality of second openings OP arranged at a second pitch and having second dimensions. The second pitch is different from the first pitch. The second dimension is different from the first dimension. Here, the “dimension” refers to the diameter of a circle (e.g., insert diameter) when the opening is circular, or at least one of the major and minor diameters of an ellipse when the opening is oval. When the opening is oval, the first dimension and the second dimension are compared with each other by comparing the major or minor diameters of the ovals.

The second film F2 may be formed by pattern inversion. For example, a fourth film is formed on the first film F1, and the fourth film is patterned through photolithography and etching. Thereafter, a fifth film is formed on the patterned fourth film, and the opening of the fourth film is filled with the fifth film. The patterned fourth film is then removed by lift-off, and the remaining fifth film becomes the second film F2. Pattern inversion technology is described, for example, in Japanese Patent Application Publication No. 2021-173638 filed on Oct. 25, 2021. The entirety of Japanese Patent Application Publication No. 2021-173638 is hereby incorporated by reference.

The third film F3 may be a silicon-containing film or a nitride film. The silicon-containing film may be a silicon nitride film (SiN film) or a silicon carbonitride film (SiCN film). The third film F3 may be an etching stop layer.

The underlayer region UR may include at least one film for a memory device such as a DRAM or a 3D-NAND.

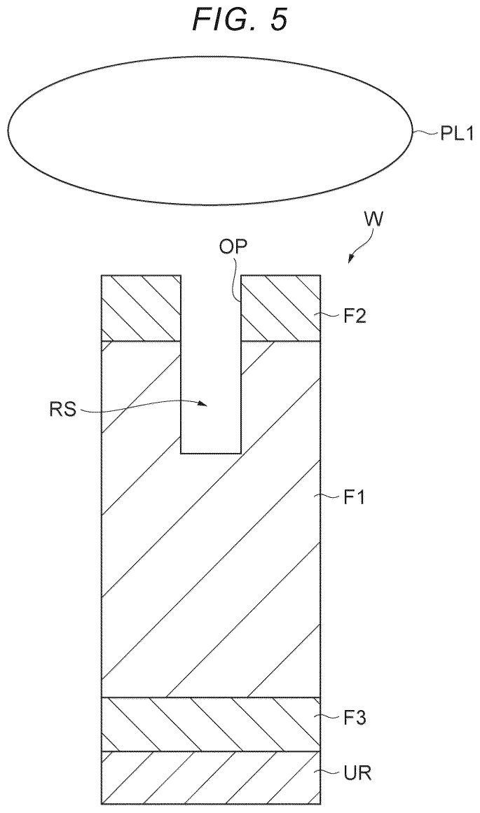

Hereinafter, the method MT1 will be described by taking an example where the method MT1 is applied to the substrate W using the plasma processing apparatus 1 of the embodiment described above, with reference to FIGS. 3 to 13. FIGS. 5 to 9 are cross-sectional views illustrating a step of the etching method according to one exemplary embodiment. When the plasma processing apparatus 1 is used, the method MT1 may be performed in the plasma processing apparatus 1 under the control of each part of the plasma processing apparatus 1 by the controller 2. With the method MT1, as shown in FIG. 2, the substrate W on the substrate support 11 disposed in the plasma processing chamber 10 is processed.

As shown in FIG. 3, the method MT1 may include step ST1 to step ST5. Step ST1 to step ST5 may be performed sequentially. Steps ST1 to ST5 may be performed in-situ. The method MT1 may eliminate at least one of step ST1, step ST2, and step ST5. Step ST1 may be performed after step ST4 or step ST5.

### Step ST1

In step ST1, the plasma processing chamber 10 is cleaned. In step ST1, a cleaning gas may be used. The cleaning gas may contain fluorine, chlorine, or oxygen.

### Step ST2

In step ST2, the inner wall of the plasma processing chamber 10 is pre-coated. In step ST2, a pre-coating gas may be used. The pre-coating gas may contain at least one of a silicon tetrachloride (SiCl₄) gas or an aminosilane-based gas.

### Step ST3

In step ST3, the substrate W illustrated in FIG. 4 is provided. The substrate W may be provided in the plasma processing chamber 10. The substrate W may be supported by the substrate support 11 in the plasma processing chamber 10. The underlayer region UR may be disposed between the substrate support 11 and the third film F3.

### Step ST4

In step ST4, the first film F1 is etched through the opening OP as shown in FIGS. 5 to 7. Step ST4 may include step ST41, step ST42, and step ST43. Step ST42 may be performed after step ST41 or before step ST41. Step ST43 may be performed after step ST41 and step ST42.

### Step ST41

In step ST41, as shown in FIG. 5, the first film F1 is etched through the opening OP by a first plasma PL1 generated from a first processing gas that includes a halogen-containing gas. As a result, a recess RS corresponding to the opening OP is formed in the first film F1. The first plasma PL1 may be generated by supplying a radio-frequency power (e.g., first radio-frequency power). The radio-frequency power may be a continuous wave or a pulse. The radio-frequency power may be a source power.

In step ST41, a bias power (e.g., first bias power) may be supplied to the substrate support 11. The bias power may be a continuous wave or a pulse.

In step ST41, the first plasma PL1 may be generated under a first pressure. The first pressure may be 30 m Torr (4 Pa) or less.

In Step ST41, the temperature of the substrate support 11 may be 60° C. or higher, or 100° C. or higher.

The halogen-containing gas may include a chlorine-containing gas or a fluorine-containing gas. Examples of the chlorine-containing gas include a chlorine gas. Examples of the fluorine-containing gas include a CF₄ gas and an NF₃ gas. The first processing gas may further contain an inert gas. Examples of the inert gas include a noble gas and a nitrogen gas.

Step ST41 may include a deposition step and an etching step. The deposition step and the etching step may be separated by changing conditions for each time. The deposition step and the etching step may be separated by adjusting the source power and the bias power. The deposition step and the etching step may be separated by shifting the phase of the pulse of the source power and the phase of the pulse of the bias power.

### Step ST42

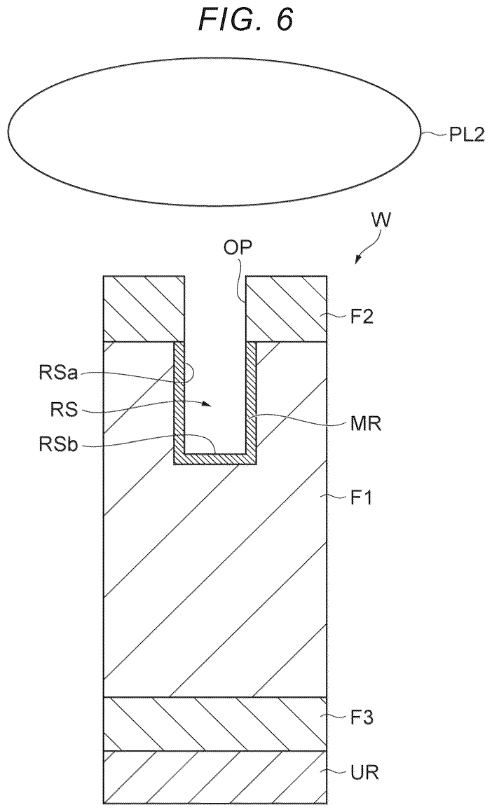

In step ST42, as shown in FIG. 6, a sidewall RSa of the recess RS formed in step ST41 is modified by a second plasma PL2 generated from a second processing gas. As a result, a modified region MR is formed at the sidewall RSa of the recess RS. The second processing gas is different from the first processing gas. The second processing gas may include an oxygen-containing gas. Examples of the oxygen-containing gas include an oxygen gas. The second processing gas may further contain an inert gas. Examples of the inert gas include a noble gas and a nitrogen gas. The modified region MR may contain an oxide of the metallic element included in the first film F1 or may contain an oxide of the non-metallic element included in the first film F1. A bottom portion RSb of the recess RS may be modified by the second plasma PL2.

In step ST42, the pressure in the plasma processing chamber 10 may be 50 m Torr (6.7 Pa) or more.

In Step ST42, the temperature of the substrate support 11 may be 60° C. or higher, or 100° C. or higher.

### Step ST43

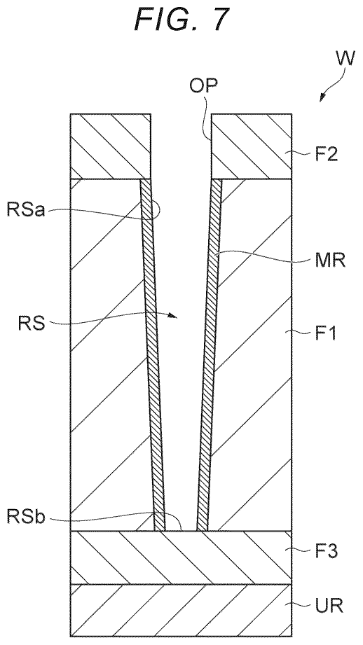

In step ST43, step ST41 and step ST42 are repeated. The modified region MR on the sidewall RSa of the recess RS suppresses the etching of the sidewall RSa in the subsequent step ST41. The modified region MR formed at the bottom portion RSb of the recess RS is removed by etching in the subsequent step ST41. As shown in FIG. 7, step ST43 may be performed until the bottom portion RSb of the recess RS reaches the third film F3.

### Step ST5

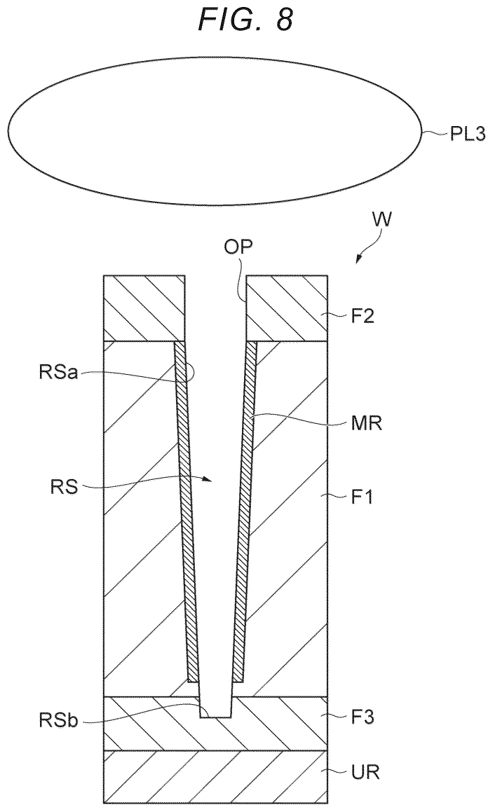

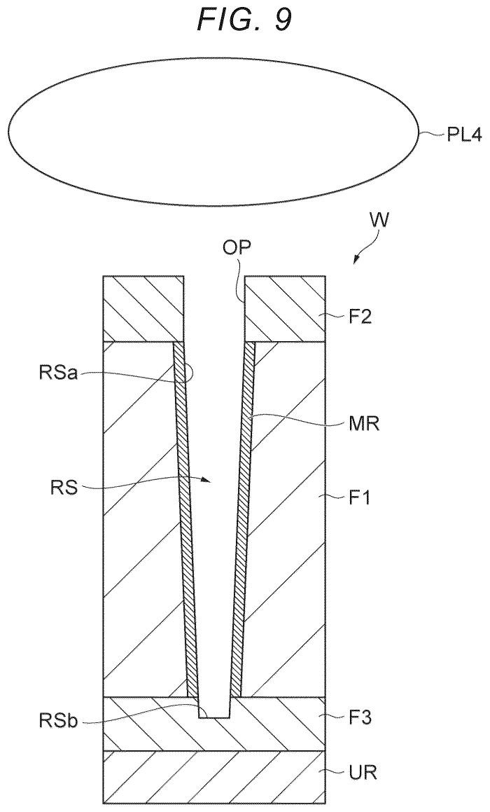

In step ST5, the first film F1 is further etched as shown in FIGS. 8 and 9. Step ST5 may be initiated in a state where the bottom portion RSb of the recess RS reaches the third film F3. Step ST5 may be an over-etching step. Step ST5 may include step ST51, step ST52, and step ST53. Step ST5 may eliminate at least one of step ST52 and step ST53. Step ST52 may be performed after step ST51 or before step ST51. Step ST53 may be performed after step ST51 and step ST52.

### Step ST51

In step ST51, the first film F1 is etched through the opening OP by a third plasma PL3 generated from a third processing gas that includes a halogen-containing gas, as shown in FIG. 8. The first film F1 may be etched in the lateral direction. In step ST51, the third film F3 may be etched with the third plasma PL3. In the lower portion of the first film F1 adjacent to the interface between the first film F1 and the third film F3, the dimension of the recess RS formed by the third plasma PL3 may be smaller than the dimension of the recess formed when the first plasma PL1 is used instead of the third plasma PL3. The etching rate of the third film F3 by the third plasma PL3 may be lower than the etching rate of the first film F1 by the third plasma PL3, or may be higher than the etching rate of the third film F3 by the first plasma PL1. The dimension of the recess refers to the length in the direction perpendicular to the depth direction of the recess. Alternatively, the dimension of the recess refers to the insert diameter of the recess.

The third plasma PL3 may be generated by supplying a radio-frequency power (e.g., second radio-frequency power). The radio-frequency power may be a continuous wave or a pulse. The radio-frequency power may be a source power. When the power is a pulse, the energy per unit time of the power is the average value of the pulse. For example, when the power in the ON state of the pulse is 100 W, the power in the OFF state of the pulse is 0 W, and the duty ratio (i.e., duty cycle) is 50%, the average value of the pulse is 50 W.

In step ST51, a bias power (e.g., second bias power) may be supplied to the substrate support 11. The bias power may be a continuous wave or a pulse. The energy per unit time of the second bias power in step ST51 may be larger than the energy per unit time of the first bias power in step ST41. As a result, in step ST51, the etching rate of the third film F3 by the third plasma PL3 increases.

The first bias power in step ST41 may be a first pulse. The second bias power in step ST51 may be a second pulse. The product (e.g., effective power) of the duty cycle and the amplitude of the second pulse may be larger than the product (e.g., effective power) of the duty ratio (i.e., duty cycle) and the amplitude of the first pulse. Accordingly, the energy per unit time of the second bias power may be larger than the energy per unit time of the first bias power. For example, when the duty ratio (i.e., duty cycle) of the second pulse is larger than the duty ratio (i.e., duty cycle) of the first pulse, the energy per unit time of the second bias power can be increased. For example, when the maximum value of the second pulse is larger than the maximum value of the first pulse, the energy per unit time of the second bias power can be increased.

The example of the type of gas included in the third processing gas may be the same as the example of the type of gas included in the first processing gas. The third processing gas may include a reaction-promoting gas that increases the etching rate of the third film F3 by the third plasma PL3. The reaction-promoting gas may include at least one of a hydrogen-containing gas and a CₓH_{y}F_{z} (x is an integer of 1 or more, and y and z are integers of 0 or more). The hydrogen-containing gas may be a hydrogen gas. The CₓH_{y}F_{z} gas may be a fluorocarbon gas, a hydrofluorocarbon gas, or a hydrocarbon gas. The third processing gas may include a reaction-promoting gas as the halogen-containing gas, or may include a reaction-promoting gas in addition to the halogen-containing gas. The third processing gas may further include an oxygen-containing gas. Examples of the oxygen-containing gas include an oxygen gas.

In step ST51, the third plasma PL3 may be generated under a second pressure. The second pressure in step ST51 may be lower than the first pressure in step ST41. As a result, in step ST51, the anisotropy of the etching increases, and thus the etching rate of the third film F3 by the third plasma PL3 increases.

In step ST51, the temperature of the substrate support 11 may be changed to increase the etching rate of the third film F3 by the third plasma PL3.

The total flow rate of the third processing gas in step ST51 may be higher than the total flow rate of the first processing gas in step ST41. Accordingly, the residence time of the gas in step ST51 can be shortened. Therefore, the reaction products in the vicinity of the bottom portion RSb of the recess RS can be quickly separated. Specifically, the exhaust is accelerated, and the reaction products are easily removed from the recess RS. The reactive species contributing to the shape abnormality (e.g., notching) do not accumulate in the vicinity of the bottom portion RSb of the recess RS, and are easily exhausted. When the total flow rate of the gas is increased, the pressure may be set to be constant in step ST41 and step ST51, and the flow rate of each gas may be set to be constant in step ST41 and step ST51.

### Step ST52

In step ST52, the sidewall RSa of the recess RS formed in step ST51 is modified by a fourth plasma PL4 generated from a fourth processing gas, as shown in FIG. 9. As a result, the modified region MR is formed at the sidewall RSa of the recess RS in the lower portion of the first film F1 adjacent to the interface between the first film F1 and the third film F3. The example of the type of gas included in the fourth processing gas may be the same as the example of the type of gas included in the second processing gas. The partial pressure of the oxygen-containing gas in the fourth processing gas may be lower than the partial pressure of the oxygen-containing gas in the second processing gas.

### Step ST53

In step ST53, step ST51 and step ST52 are repeated. The modified region MR on the sidewall RSa of the recess RS suppresses the etching of the sidewall RSa in the subsequent step ST51. Step ST53 may be performed until the dimension (CD) of the bottom portion RSb of the recess RS reaches a desired dimension.

After step ST4 or step ST5, the aspect ratio of the recess RS may be 5 or more, or may be 10 or more. The aspect ratio of the recess RS is represented by D1/D2, where D1 is the depth of the recess RS, and D2 is the dimension of the recess RS at the upper end of the recess RS.

After step ST5, the modified region MR on the sidewall RSa of the recess RS may be removed by, for example, dilute hydrofluoric acid (DHF).

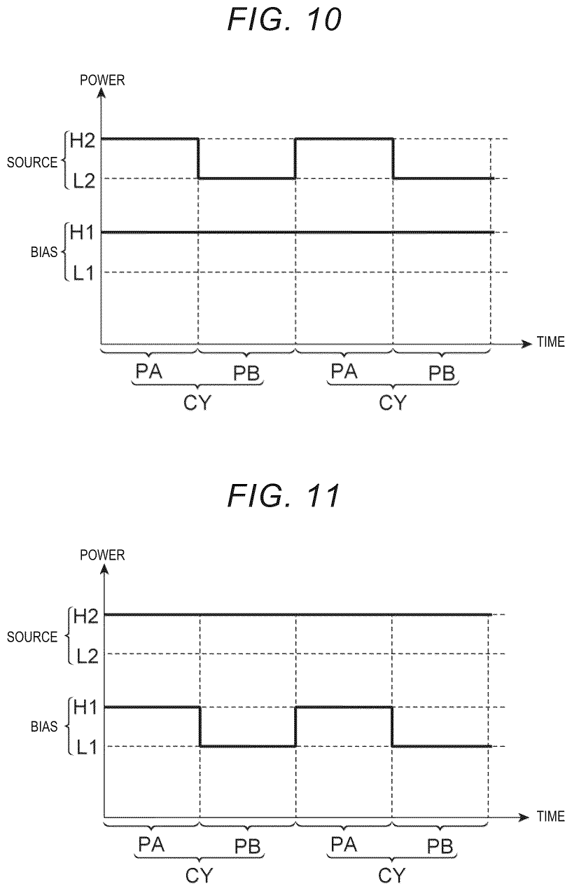

FIGS. 10 to 13 are examples of timing charts illustrating temporal changes of the source power and the bias power. These timing charts relate to step ST41. The source power may be a radio-frequency power HF provided to a counter electrode (e.g., upper electrode). The bias power may be a radio-frequency power LF provided to the electrode in the main body 111 of the substrate support 11. When the pulse of the power is supplied, the pulse may be generated by switching ON/OFF of the power, or the pulse may be generated based on the magnitude of a power value.

As shown in FIG. 10, in step ST41, the pulse of the source power may be supplied, and the continuous wave of the bias power may be supplied. The source power may be periodically applied in a cycle CY. The cycle CY may include a first period PA and a second period PB. The second period PB follows the first period PA. In the first period PA, the source power may be maintained at high power H2, and the bias power may be maintained at high power H1. In the second period PB, the source power may be maintained at low power L2, and the bias power may be maintained at high power H1. The low power L2 may be 0 W.

As shown in FIG. 11, in step ST41, the continuous wave of the source power may be supplied, and the pulse of the bias power may be supplied. The bias power may be periodically applied in the cycle CY. In the first period PA, the bias power may be maintained at high power H1 and the source power may be maintained at high power H2. In the second period PB, the bias power may be maintained at low power L1, and the source power may be maintained at high power H2. The low power L1 may be 0 W.

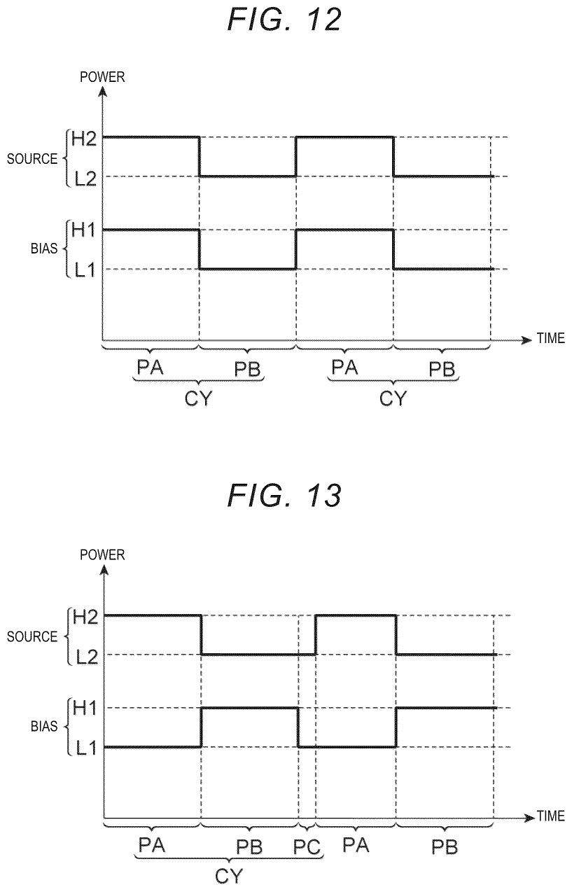

As shown in FIG. 12, in step ST41, the pulse of the source power may be supplied, and the pulse of the bias power may be supplied. The source power and the bias power may be periodically applied in the cycle CY. The pulse of the source power may be synchronized with the pulse of the bias power. In the first period PA, the bias power may be maintained at high power H1 and the source power may be maintained at high power H2. In the second period PB, the bias power may be maintained at low power L1 and the source power may be maintained at low power L2.

As shown in FIG. 13, in step ST41, the pulse of the source power may be supplied, and the pulse of the bias power may be supplied. The source power and the bias power may be periodically applied in the cycle CY. The cycle CY may include the first period PA, the second period PB, and a third period PC. The third period PC follows the second period PB. The phase of the pulse of the source power may be shifted from the phase of the pulse of the bias power. In the first period PA, the bias power may be maintained at low power L1, and the source power may be maintained at high power H2. In the first period PA, the first plasma PL1 (e.g., see FIG. 5) is generated. In the second period PB, the bias power may be maintained at high power H1, and the source power may be maintained at low power L2. In the second period PB, ions having high energy collide with the bottom portion RSb of the recess RS. In the third period PC, the bias power may be maintained at low power L1, and the source power may be maintained at low power L2. In the third period PC, the by-products of the etching are exhausted from the recess RS.

With the plasma processing apparatus 1 and the method MT1 described above, because the first plasma PL1 is generated by the pulse of the radio-frequency power, excessive dissociation of the halogen-containing gas is suppressed. Therefore, the etching of the sidewall RSa of the recess RS is suppressed. Accordingly, the first film F1 can be etched while the shape abnormality (bowing) of the sidewall RSa of the recess RS is being suppressed. Therefore, This improves the verticality of the sidewall RSa of the recess RS and the local dimensional uniformity of the recess RS, and also improves the in-plane uniformity of the etching rate of the first film F1. Further, when excessive dissociation of the halogen-containing gas is suppressed, the etching amount of the second film F2 can be reduced. Therefore, the etching selectivity of the first film F1 to the second film F2 can be improved.

According to the plasma processing apparatus 1 and the method MT1 described above, in step ST5, the difference between the etching rate of the third film F3 and the etching rate of the first film F1 can be reduced. Therefore, in step ST5, the side etching in the sidewall RSa of the recess RS can be suppressed in the lower portion of the first film F1 adjacent to the interface between the first film F1 and the third film F3. Therefore, the notching caused by the side etching may be suppressed. Therefore, the first film F1 can be etched while shape abnormality (notching) is suppressed.

When the occurrence of the notching is suppressed, the dimensional uniformity of the bottom portion RSb of the recess RS can be improved. As an indicator of dimensional uniformity, the value (36) of local CD uniformity (LCDU) is used. A decrease in the value of LCDU indicates an improvement in dimensional uniformity. According to the plasma processing apparatus 1 and the method MT1 described above, the value of LCDU in the recess RS can be reduced to, for example, 1.5 nm or less.

Hereinafter, various experiments performed to evaluate the method MT1 will be described. The following experiments are not intended to limit the present disclosure.

### First Experiment

In a first experiment, a substrate having a WSi film and a mask on the WSi film was prepared. The mask is a silicon oxide film having an opening. Steps ST41 to ST43 of the method MT1 were performed on the substrate to etch the WSi film. In step ST41, a processing gas that includes a chlorine gas was used. In step ST41, plasma was generated by the pulse of the source power (radio-frequency power HF). The duty ratio (i.e., duty cycle) of the pulse is 75%. In step ST42, a processing gas that includes an oxygen gas was used.

### Second Experiment

A second experiment was performed in the same manner as in the first experiment except that the duty ratio (i.e., duty cycle) of the pulse was 50%.

### Third Experiment

A third experiment was performed in the same manner as in the first experiment except that a continuous wave of a source power was used instead of the pulse of the source power.

### Test Results

The etching selectivity of the WSi film to the mask was calculated by measuring the depth of the recess formed in the WSi film and the remaining thickness of the mask in the cross-section of the substrate. The etching selectivity in the first experiment was 2.44. The etching selectivity in the second experiment was 2.90. The etching selectivity in the third experiment was 2.16. Therefore, it is understood that the etching selectivity is improved by using the pulse of the source power. Further, it is understood that the etching selectivity is improved by reducing the duty ratio (i.e., duty cycle) of the pulse.

### Fourth Experiment

In a fourth experiment, a substrate having a WSi film and a mask on the WSi film was prepared. The mask is a silicon oxide film having a plurality of hole patterns. Step ST41 to step ST43 and step ST51 of the method MT1 were performed on the substrate to etch the WSi film. Steps ST52 and step ST53 were not performed. In step ST41 and step ST51, a processing gas that includes a chlorine gas was used. In step ST42, a processing gas that includes an oxygen gas was used.

### Fifth Experiment

After step ST51, a fifth experiment was performed in the same manner as in the fourth experiment except that step ST52 and step ST53 were performed. In step ST52, a processing gas that includes an oxygen gas was used.

### Test Results

The values of LCDU were calculated from the dimensions at the bottom of a plurality of recesses (e.g., holes) formed in the WSi film. The value of LCDU in the fourth experiment was smaller than the value of LCDU in the fifth experiment. Therefore, it can be understood that dimensional uniformity of the bottom portion RSb of the recess RS is improved by not modifying the sidewall RSa of the recess RS in the over-etching step.

### Sixth Experiment

In a sixth experiment, a substrate having a WSi film and a mask on the WSi film was prepared. The mask is a silicon oxide film having a plurality of hole patterns. Step ST41 to step ST43 and step ST51 of the method MT1 were performed on the substrate to etch the WSi film. Steps ST52 and step ST53 were not performed. In step ST41 and step ST51, a processing gas that includes a chlorine gas was used. In step ST42, a processing gas that includes an oxygen gas was used. In step ST51, plasma was generated by the pulse of the bias radio-frequency power.

### Seventh Experiment

A seventh experiment was performed in the same manner as in the sixth experiment except that the duty ratio (i.e., duty cycle) of the pulse was increased by 5% in step ST51.

### Eighth Experiment

An eighth experiment was performed in the same manner as in the sixth experiment except that the duty ratio (i.e., duty cycle) of the pulse was increased by 15% in step ST51.

### Ninth Experiment

A ninth experiment was performed in the same manner as in the sixth experiment except that a processing gas that includes an oxygen gas and a hydrofluorocarbon gas was used in step ST51.

### Test Results

The values of LCDU were calculated from the dimensions at the bottom of a plurality of recesses (holes) formed in the WSi film. The values of LCDU in the seventh and eighth experiments were smaller than the value of LCDU in the sixth experiment. Therefore, it can be understood that the dimensional uniformity of the bottom portion RSb of the recess RS is improved by increasing the duty ratio (i.e., duty cycle) of the pulse of the bias radio-frequency power in the etching step of the over-etching step.

The value of LCDU in the ninth experiment was smaller than the value of LCDU in the sixth experiment. Therefore, it can be understood that the dimensional uniformity of the bottom portion RSb of the recess RS is improved by using the processing gas that includes the hydrofluorocarbon gas in the etching step of the over-etching step.

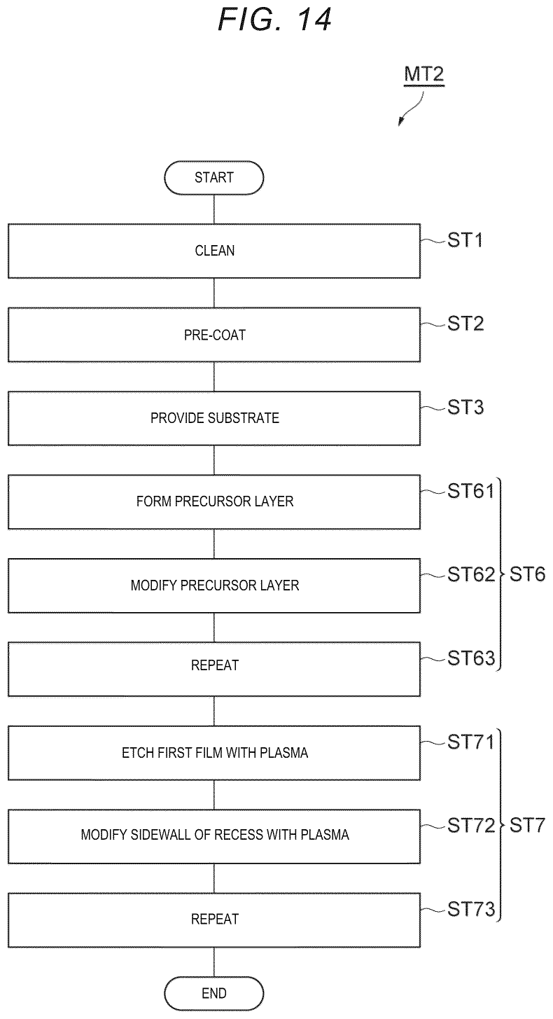

FIG. 14 is a flowchart of an etching method according to one exemplary embodiment. An etching method MT2 illustrated in FIG. 14 (hereinafter referred to as “method MT2”) may be performed by the plasma processing apparatus 1 of the embodiment. The method MT2 may be applied to the substrate W of FIG. 4.

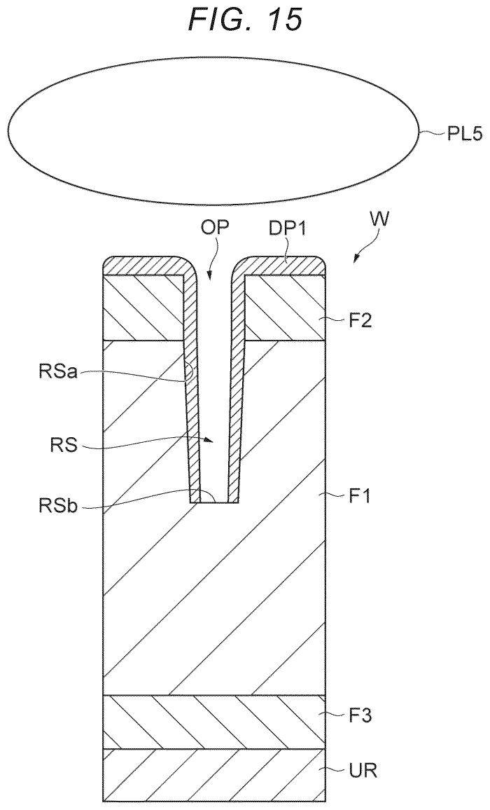

Hereinafter, the method MT2 will be described by taking as an example a case where the method MT2 is applied to the substrate W using the plasma processing apparatus 1 of the embodiment described above, with reference to FIGS. 14 to 18. FIGS. 15 to 18 are cross-sectional views illustrating a step of the etching method according to one exemplary embodiment. In a case where the plasma processing apparatus 1 is used, the method MT2 may be performed in the plasma processing apparatus 1 under the control of each part of the plasma processing apparatus 1 by the controller 2. In the method MT2, as shown in FIG. 2, the substrate W on the substrate support 11 disposed in the plasma processing chamber 10 is processed.

As shown in FIG. 14, the method MT2 may include Step ST1 to Step ST3, and Step ST6 to Step ST7. Steps ST1 to ST3 and steps ST6 to ST7 may be performed sequentially. Steps ST1 to ST3 and steps ST6 to ST7 may be performed in-situ. The method MT2 may eliminate at least one of Step ST1 and Step ST2. Step ST1 may be performed after Step ST7. Step ST1 to Step ST3 may be performed in the same manner as Step ST1 to Step ST3 of the method MT1.

### Step ST6

In step ST6, as shown in FIG. 15, a protective film DP1 is formed on the sidewall RSa of the recess RS formed in the first film F1 corresponding to the opening OP. The protective film DP1 may not be formed at the bottom portion RSb of the recess RS, or may be formed at the bottom portion RSb of the recess RS. The protective film DP1 may be formed on the second film F2. The protective film DP1 may be formed of a plasma PL5 generated from the processing gas. The protective film DP1 may be formed by CVD. In step ST6, the thickness of the protective film DP1 on the sidewall RSa of the recess RS can be made larger than the thickness of the protective film DP on the bottom portion RSb of the recess RS by increasing the pressure or adjusting the temperature.

The processing gas in step ST6 may include at least one of a silicon-containing gas, a carbon-containing gas, a boron-containing gas, a phosphorus-containing gas, a metal-containing gas, a sulfur-containing gas, a bromine-containing gas, and an iodine-containing gas. Examples of the silicon-containing gas include a SiCl₄ gas and a SiF₄ gas. Examples of the carbon-containing gas include a fluorocarbon gas, a hydrofluorocarbon gas, and a hydrocarbon gas. Examples of the boron-containing gas include a BCl₃ gas. Examples of the phosphorus-containing gas include a PFₓ gas. Examples of the metal-containing gas include a WF₆ gas and a TiCl₄ gas. Examples of the sulfur-containing gas include an SO₂ gas and a COS gas. Examples of the bromine-containing gas include a HBr gas. Examples of the iodine-containing gas include H1.

The processing gas of a first example in step ST6 includes a HBr gas. The processing gas of the first example may further contain an oxygen gas. In this case, the protective film DP1 contains SiBrₓO_{y}.

The processing gas in a second example in step ST6 includes a SiCl₄ gas and an oxygen gas. In this case, the protective film DP1 includes SiOₓ.

The processing gas in a third example in step ST6 includes a BCl₃ gas and an oxygen gas. In this case, the protective film DP1 contains BOₓ.

The processing gas in a fourth example in step ST6 includes a C₄F₈ gas or a C₄F₆ gas. In this case, the protective film DP1 contains CₓF_{y}.

The processing gas in a fifth example in step ST6 includes a CH₃F gas or a CH₄ gas. In this case, the protective film DP1 contains CₓH_{y}.

The processing gas in a sixth example in step ST6 includes a COS gas or a CHₓF_{y} gas.

The recess RS may be formed by etching performed at the same time as or before step ST6. In this case, the etching may be performed in the same manner as the etching in step ST7.

### Step ST7

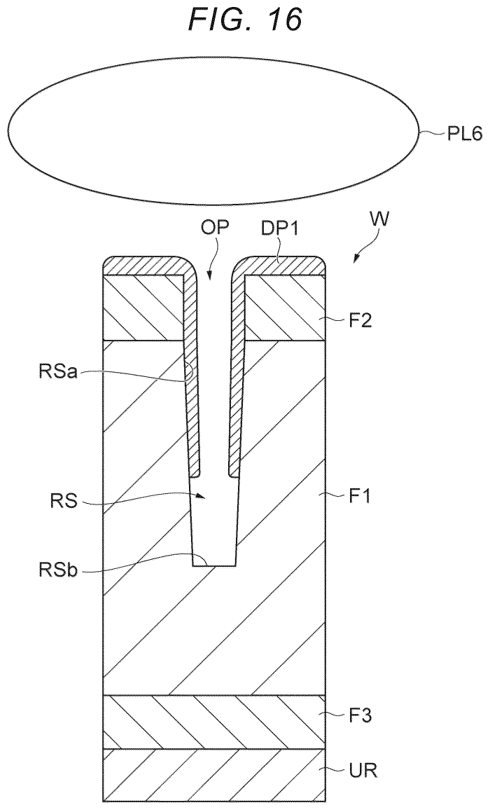

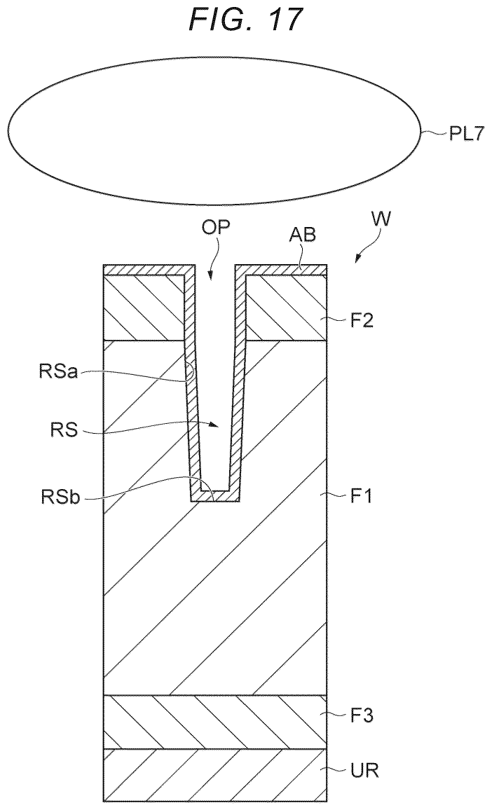

In step ST7, as shown in FIG. 16, the first film F1 is etched through the opening OP by a plasma PL6 generated from the processing gas that includes a halogen-containing gas. Step ST7 may be performed at the same time as step ST6. The plasma processing chamber in which step ST7 is performed may be the same as or different from the plasma processing chamber in which step ST6 is performed.

Step ST7 may include step ST71, step ST72, and step ST73. Step ST7 may eliminate at least one of step ST72 and step ST73. Step ST72 may be performed after step ST71 or before step ST71. Step ST73 may be performed after step ST71 and step ST72. Step ST6 may be performed between step ST71 and step ST72, or may be performed between step ST72 and step ST73. Step ST6 may be performed at the same time as step ST71 or may be performed at the same time as step ST72.

### Step ST71

In step ST71, as shown in FIG. 16, the first film F1 is etched through the opening OP by the plasma PL6. As a result, since the bottom portion RSb of the recess RS is etched, the recess RS is deeper. Step ST71 may be performed in the same manner as in step ST41 of the method MT1.

### Step ST72

Step ST72 may be performed in the same manner as in step ST42 of the method MT1.

### Step ST73

In step ST73, step ST71 and step ST72 are repeated.

After step ST7, the thickness of the protective film DP1 may be 25% or less of the dimension of the recess RS. For example, when the dimension of the recess RS is 20 nm, the thickness of the protective film DP1 may be 5 nm or less.

After step ST7, the protective film DP1 may be removed by, for example, dilute hydrofluoric acid (DHF).

According to the plasma processing apparatus 1 and the method MT2 described above, in step ST7, the etching of the sidewall RSa is suppressed by the protective film DP1 on the sidewall RSa of the recess RS of the first film F1. Accordingly, the first film F1 can be etched while suppressing shape abnormalities (bowing). Further, the value of LCDU in the bottom portion RSb of the recess RS can also be reduced. Further, the etching of the second film F2 is suppressed by the protective film DP1 on the second film F2. Therefore, the etching selectivity of the first film F1 to the second film F2 can be improved.

As shown in FIG. 14, in the method MT2, step ST6 may include step ST61, step ST62, and step ST63. Steps ST61, ST62, and ST63 may be performed sequentially. Step ST6 may not include step ST63.

In step ST61, as shown in FIG. 17, a precursor layer AB is formed on the sidewall RSa of the recess RS. The precursor layer AB may be an adsorption layer. In step ST61, a plasma PL7 may be generated from a precursor gas for forming the precursor layer AB. The precursor layer AB may be formed by exposing the substrate W to a precursor gas without generating the plasma PL7. Examples of the precursor gas include an aminosilane-based gas. Chemical species in the plasma PL7 may form the precursor layer AB. The precursor layer AB may not be formed on the bottom portion RSb of the recess RS, or may be formed on the bottom portion RSb of the recess RS. The precursor layer AB may be formed on the second film F2.

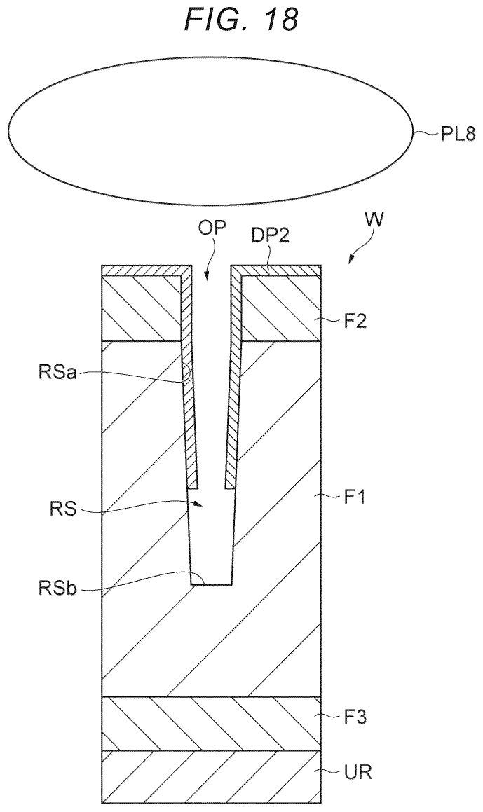

In step ST62, the precursor layer AB may be modified as shown in FIG. 18. A protective film DP2 is formed by modifying the precursor layer AB. In step ST62, a plasma PL8 may be generated from a processing gas that includes a modification gas for modifying the precursor layer AB. The modification gas may include an oxygen-containing gas. The processing gas may further contain an inert gas. Chemical species in the plasma PL8 may modify the precursor layer AB. The chemical species used in step ST62 may be the same as or different from the etchant in the plasma PL6 in step ST7. Step ST62 may be performed at the same time as step ST7 or before step ST7.

In step ST63, the step of forming the precursor layer AB and the step of modifying the precursor layer AB are repeated.

The gas introduction port 13c (see, FIG. 2) through which the modification gas for modifying the precursor layer AB is supplied in step ST62 may be different from the gas introduction port 13c through which the precursor gas for forming the precursor layer AB is supplied in step ST61. As a result, it is possible to suppress the blockage of the gas introduction port 13c caused by the deposition of the protective film DP2 in the vicinity of the gas introduction port 13c.

At least one of the period for supplying the precursor gas in step ST61, the period for supplying the modification gas in step ST62, and the period for supplying the processing gas in step ST7 may be changed according to the depth or the specification of the recess RS. At least one of the period for supplying the precursor gas in step ST61, the period for supplying the modification gas in step ST62, and the period for supplying the processing gas in step ST7 may be longer as the recess RS becomes deeper. For example, when the recess RS is deeper, the precursor gas is less likely to reach the bottom portion RSb of the recess RS. When the period for supplying the precursor gas in step ST61 is made longer as the recess RS becomes deeper, the precursor gas easily reaches the bottom portion RSb of the recess RS.

As described above, the protective film DP2 may be formed by ALD. In step ST62, chemical species (for example, oxygen radicals) in the plasma PL8 are easily adsorbed onto the surface of the precursor layer AB. Therefore, the probability of adsorption of chemical species in the plasma PL8 increases at the sidewall RSa of the recess RS, and the probability of adsorption of chemical species in the plasma PL8 decreases at the bottom portion RSb of the recess RS. Accordingly, the protective film DP2 is easily formed on the sidewall RSa, but is less likely to be formed at the bottom portion RSb. Therefore, in step ST7, the sidewall RSa is less likely to be etched, and the bottom portion RSb is easily etched.

Further, since the protective film DP2 is relatively thin, blockage by the protective film DP2 is less likely to occur at the upper end of the sidewall RSa of the recess RS.

When step ST62 is performed at the same time as step ST7, the protective film DP2 is removed by etching even when the protective film DP2 is formed at the bottom portion RSb of the recess RS. Meanwhile, the protective film DP2 is formed on the sidewall RSa of the recess RS.

Hereinafter, various experiments performed to evaluate the method MT2 will be described. The following experiments are not intended to limit the present disclosure.

### Tenth Experiment

In a tenth experiment, a substrate having a WSi film and a mask on the WSi film was prepared. The mask is a silicon oxide film having an opening. With respect to this substrate, steps ST6 to ST7 of the method MT2 were performed to etch the WSi film. Step ST71 was performed at the same time as step ST6. In step ST6 and step ST71, a processing gas containing a chlorine gas and a SiCl₄ gas was used. In step ST72, a processing gas that includes an oxygen gas was used.

### Eleventh Experiment

An eleventh experiment was performed in the same manner as in the tenth experiment except that the processing gas did not contain a SiCl₄ gas in step ST6 and step ST71.

### Twelfth Experiment

A twelfth experiment was performed in the same manner as in the tenth experiment except that the processing gas further included an oxygen gas in step ST6 and step ST71.

### Thirteenth Experiment

A thirteenth experiment was performed in the same manner as in the twelfth experiment except that the processing gas did not contain a SiCl₄ gas in step ST6 and step ST71.

### Test Results

In the cross-section of the substrate, the etching selectivity of the WSi film to the mask was calculated by measuring the depth of the recess formed in the WSi film and the remaining thickness of the mask. The etching selectivity in the tenth experiment was 4.43. The etching selectivity in the eleventh experiment was 2.37. The etching selectivity in the twelfth experiment was 5.22. The etching selectivity in the thirteenth experiment was 3.76. Therefore, it can be understood that in step ST6, the etching selectivity is improved by forming a silicon oxide film on the mask by a SiCl₄ gas.

### Fourteenth Experiment

In a fourteenth experiment, a substrate having a WSi film and a mask on the WSi film was prepared. The mask is a silicon oxide film having a plurality of hole patterns. With respect to this substrate, steps ST6 to ST7 of the method MT2 were performed to etch the WSi film. Step ST71 was performed at the same time as step ST6. In step ST6 and step ST71, a processing gas containing a chlorine gas, an NF₃ gas, an oxygen gas, and a SiCl₄ gas was used. In step ST72, a processing gas that includes an oxygen gas was used.

### Fifteenth Experiment

A fifteenth experiment was performed in the same manner as in the fourteenth experiment except that a processing gas containing a chlorine gas, a helium gas, and a CF 4 gas was used in step ST6 and step ST71. The processing gas does not include a SiCl₄ gas.

### Test Results

The values of LCDU were calculated from the dimensions at the bottom of a plurality of recesses (holes) formed in the WSi film. The value of LCDU in the fourteenth experiment was 1.5 nm. The value of LCDU in the fifteenth experiment was 2.1 nm. Therefore, it can be understood that the dimensional uniformity of the recess is improved by forming the silicon oxide film on the sidewall of the recess by SiCl₄ gas.

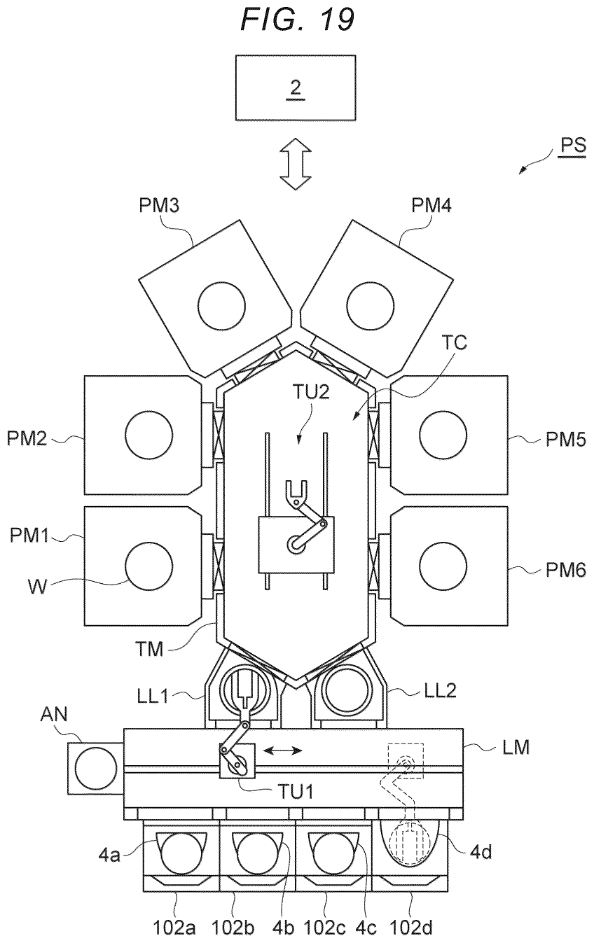

FIG. 19 shows a substrate processing system according to one exemplary embodiment. A substrate processing system PS shown in FIG. 19 may be used in the method MT1 or the method MT2. The substrate processing system PS includes load ports 102a-102d, containers 4a-4d, loader module LM, aligner AN, load-lock modules LL1 and LL2, process modules PM1 to PM6, a transfer module TM, and the controller 2. The number of load ports, number of containers, and number of load-lock modules in the substrate processing system PS can be any one or more. Further, the substrate processing system PS may include one or more process modules.

The load ports 102a to 102d are arranged along one edge of the loader module LM. The containers 4a to 4d are placed on the load ports 102a to 102d, respectively. Each of the containers 4a to 4d is, for example, a container referred to as a front opening unified pod (FOUP). Each of the containers 4a to 4d is configured to accommodate the substrate W therein.

The loader module LM has a chamber. A pressure in the chamber of the loader module LM is set to an atmospheric pressure. The loader module LM has a transfer device TU1. The transfer device TU1 is, for example, a transfer robot and is controlled by the controller 2. The transfer device TU1 is configured to transfer the substrate W through the chamber of the loader module LM. The transfer device TU1 can transfer the substrate W between each of the containers 4a to 4d and the aligner AN, between the aligner AN and each of the load-lock modules LL1 and LL2, and between each of the load-lock modules LL1 and LL2 and each of the containers 4a to 4d. The aligner AN is connected to the loader module LM. The aligner AN is configured to adjust a position of the substrate W (calibration of the position).

Each of the load-lock modules LL1 and LL2 is disposed between the loader module LM and the transfer module TM. Each of the load-lock module LL1 and the load-lock module LL2 has a preliminary decompression chamber.

The transfer module TM is connected to each of the load-lock modules LL1 and LL2 through gate valves. The transfer module TM has a transfer chamber TC whose interior space is configured to be depressurizable (e.g., able to/configured to/designed to be depressurized). The transfer module TM has a transfer device TU2. The transfer device TU2 is, for example, a transfer robot and is controlled by the controller 2. The transfer device TU2 is configured to transfer the substrate W through the transfer chamber TC. The transfer device TU2 transports the substrate W between each of the load-lock modules LL1 and LL2 and each of the process modules PM1 to PM6, and between any two process modules among the process modules PM1 to PM6.

Each of the process modules PM1 to PM6 is configured to perform dedicated substrate processing. One of the process modules PM1 to PM6 may be the plasma processing apparatus 1 used in the method MT1 or the method MT2.

Step ST6 of the method MT2 may be performed in one process module among the process modules PM1 to PM6, and step ST7 of the method MT2 may be performed in another process module among the process modules PM1 to PM6.

Although various exemplary embodiments have been described above, various additions, omissions, substitutions and changes may be made without being limited to the exemplary embodiments described above. In addition, other embodiments may be formed by combining elements in different embodiments.

For example, each step of the method MT1 may be freely combined with each step of the method MT2. Step ST6 of the method MT2 may be performed between step ST3 and Step ST4 of the method MT1.

Hereinafter, various exemplary embodiments included in the present disclosure will be described in the following [E1] to [E51].

### [E1]

An etching method including:
a step (a) of providing a substrate, the substrate including a first film and a second film having openings on the first film, the first film containing a metallic element and a non-metallic element, and
a step (b) of etching the first film through the openings, in which
the step (b) includes:
   a step (i) of etching the first film through the openings with a first plasma generated from a first processing gas including a halogen-containing gas by supplying a pulse of a radio-frequency power,
   a step (ii) of modifying a sidewall of a recess formed in the step (i) with a second plasma generated from a second processing gas, and
   a step (iii) of repeating the step (i) and the step (ii).

According to the etching method [E1], since the first plasma is generated by the pulse of the radio-frequency power, excessive dissociation of the halogen-containing gas is suppressed. Therefore, the etching of the sidewall of the recess is suppressed. Therefore, according to the etching method [E1], the first film can be etched while suppressing a shape abnormality.

### [E2]

According to the etching method [E1], in the step (i), a continuous wave of a bias power is supplied to a substrate support for supporting the substrate.

### [E3]

According to the etching method [E1], in the step (i), a pulse of a bias power is supplied to a substrate support for supporting the substrate, and the pulse of the radio-frequency power and the pulse of the bias power are synchronized.

### [E4]

According to the etching method [E1], in the step (i), a pulse of a bias power is supplied to a substrate support for supporting the substrate, and a phase of the pulse of the radio-frequency power is misaligned with a phase of the pulse of the bias power.

### [E5]

An etching method including:
a step (a) of providing a substrate, the substrate including a first film, a second film having openings on the first film, and a third film below the first film, the first film containing a metallic element and a non-metallic element,
a step (b) of etching the first film through the openings, and
a step (c) of further etching the first film after the step (b), in which
the step (b) includes:
   a step (i) of etching the first film through the openings with a first plasma generated from a first processing gas that includes a halogen-containing gas,
   a step (ii) of modifying a sidewall of a recess formed in the step (i) with a second plasma generated from a second processing gas, and
   a step (iii) of repeating the step (i) and the step (ii),
the step (c) includes a step (iv) of etching the first film and the third film through the openings with a third plasma generated from a third processing gas that includes a halogen-containing gas, and
at a lower portion of the first film adjacent to an interface between the first film and the third film, a dimension of the recess formed with the third plasma is smaller than a dimension of a recess formed when the first plasma is used instead of the third plasma.

According to the etching method [E5], in the step (c), since it is possible to suppress the etching (side etching) of the sidewall of the recess, it is possible to suppress the occurrence of notching caused by the side etching. Therefore, according to the etching method [E5], the first film can be etched while suppressing a shape abnormality.

### [E6]

In the etching method according to [E5], in the step (i), a first bias power is supplied to a substrate support for supporting the substrate, and in the step (iv), a second bias power is supplied to the substrate support for supporting the substrate, and energy per unit time of the second bias power is larger than energy per unit time of the first bias power.

In this case, in the step (iv), chemical species in the third plasma are attracted toward the substrate by the second bias power. Therefore, the etching rate of the third film in the step (iv) increases.

### [E7]

In the etching method according to [E6], the first bias power is a first pulse, the second bias power is a second pulse, and a product of a duty ratio (i.e., duty cycle) and an amplitude of the second pulse is larger than a product of a duty ratio (i.e., duty cycle) and an amplitude of the first pulse.

### [E8]

In the etching method according to any one of [E5] to [E7], the third processing gas includes a reaction-promoting gas that increases an etching rate of the third film with the third plasma.

In this case, the etching rate of the third film in the step (iv) increases.

### [E9]

In the etching method according to [E8], the reaction-promoting gas includes at least one of a hydrogen-containing gas and CₓH_{y}F_{z} (x is an integer of 1 or more, y and z are integers of 0 or more) gas.

### [E10]

In the etching method according to any one of [E5] to [E9], the step (c) does not include a step of modifying the sidewall of the recess with a fourth plasma generated from a fourth processing gas.

In this case, in the step (iv), the sidewall of the recess is not excessively modified.

### [E11]

In the etching method according to any one of [E5] to [E9],
the step (c) further includes (v) a step of modifying the sidewall of the recess with a fourth plasma generated from a fourth processing gas,
in the step (ii), the second processing gas includes an oxygen-containing gas,
in the step (v), the fourth processing gas includes an oxygen-containing gas, and
a partial pressure of the oxygen-containing gas in the fourth processing gas is lower than a partial pressure of the oxygen-containing gas in the second processing gas.

In this case, in the step (iv), excessive oxidation of the sidewall of the recess can be suppressed.

### [E12]

In the etching method according to any one of [E5] to [E11],
in the step (i), a first radio-frequency power for generating the first plasma is supplied,
in the step (iv), a second radio-frequency power for generating the third plasma is supplied, and
energy per unit time of the second radio-frequency power is smaller than energy per unit time of the first radio-frequency power.

In this case, in the step (iv), excessive dissociation of the halogen-containing gas is suppressed. Therefore, the etching of the sidewall of the recess is suppressed.

### [E13]

In the etching method according to any one of [E5] to [E12],
in the step (i), the first plasma is generated under a first pressure,
in the step (iv), the third plasma is generated under a second pressure, and
the second pressure is smaller than the first pressure.

In this case, in the step (iv), anisotropy increases when chemical species in the third plasma move toward the substrate. Therefore, the etching of the sidewall of the recess is suppressed.

### [E14]

In the etching method according to any one of [E5] to [E13], the third film is an etching stop layer.

### [E15]

In the etching method according to any one of [E1] to [E14], the first film contains at least one transition metallic element selected from the group consisting of tungsten, titanium, molybdenum, hafnium, zirconium, and ruthenium, as the metallic element.

### [E16]

In the etching method according to any one of [E1] to [E15], the first film contains at least one of silicon, carbon, nitrogen, oxygen, hydrogen, boron, and phosphorus, as the non-metallic element.

### [E17]

In the etching method according to [E16], the first film contains at least one tungsten compound selected from the group consisting of tungsten silicide, tungsten silicon nitride, tungsten silicon boron, and tungsten silicon carbon.

### [E18]

In the etching method according to any one of [E1] to [E17], the second film is a mask.

### [E19]

In the etching method according to any one of [E1] to [E18], in the step (i), a temperature of the substrate support for supporting the substrate is 60° C. or higher.

### [E20]

In the etching method according to any one of [E1] to [E19], the second film includes a plurality of first openings arranged at a first pitch and having a first dimension, and a plurality of second openings arranged at a second pitch and having a second dimension, and the second pitch is different from the first pitch and the second dimension is different from the first dimension.

### [E21]

In the etching method according to any one of [E1] to [E20], after the step (iii), an aspect ratio of the recess is 5 or more.

### [E22]

The etching method according to any one of [E1] to [E21], further including: (d) before the step (a) or after the step (b), a step of cleaning a chamber in which the first plasma is generated.

### [E23]

The etching method according to any one of [E1] to [E22], further including: (e) before the step (a), a step of pre-coating an inner wall of a chamber in which the first plasma is generated.

### [E24]

In the etching method according to any one of [E1] to [E23], the step (a) and the step (b) are performed in-situ.

### [E25]

A plasma processing apparatus including:
a chamber,
a substrate support for supporting a substrate in the chamber, the substrate including a first film and a second film having openings on the first film, the first film containing a metallic element and a non-metallic element,
a gas supply configured to supply a first processing gas and a second processing gas into the chamber, the first processing gas including a halogen-containing gas,
a plasma generator configured to generate a first plasma from the first processing gas in the chamber and a second plasma from the second processing gas in the chamber, and
a controller, in which
the controller is configured to cause the gas supply and the plasma generator to perform:
   a step (i) of etching the first film through the openings with the first plasma by supplying a pulse of a radio-frequency power,
   a step (ii) of modifying a sidewall of a recess formed in the step (i) with the second plasma, and
   a step (iii) of repeating the step (i) and the step (ii).

### [E26]

A plasma processing apparatus including:
a chamber,
a substrate support for supporting a substrate in the chamber, the substrate including a first film, a second film having openings on the first film, and a third film below the first film, the first film containing a metallic element and a non-metallic element,
a gas supply configured to supply a first processing gas, a second processing gas, and a third processing gas into the chamber, the first processing gas including a halogen-containing gas, the third processing gas including a halogen-containing gas,
a plasma generator configured to generate a first plasma from the first processing gas in the chamber, a second plasma from the second processing gas in the chamber, and a third plasma from the third processing gas in the chamber, and
a controller, in which
the controller is configured to cause the gas supply and the plasma generator to perform:
   a step (i) of etching the first film through the openings with the first plasma,
   a step (ii) of modifying a sidewall of a recess formed in the step (i) with the second plasma,
   a step (iii) of repeating the step (i) and the step (ii), and
   a step (iv) of etching the first film and the third film through the openings with the third plasma, after the step (iii), and
the controller is configured to control the gas supply and the plasma generator so that at a lower portion of the first film adjacent to an interface between the first film and the third film, a dimension of the recess formed with the third plasma is smaller than a dimension of the recess formed when the first plasma is used instead of the third plasma.

### [E27]

In the etching method according to any one of [E1] to [E24], the substrate further includes a third film below the first film, the etching method further includes a step (c) of further etching the first film, after the step (b), the step (c) includes a step (iv) of etching the first film and the third film through the openings with a third plasma generated from a third processing gas that includes a halogen-containing gas, and at a lower portion of the first film adjacent to an interface between the first film and the third film, a dimension of the recess formed with the third plasma is smaller than a dimension of a recess formed when the first plasma is used instead of the third plasma.

### [E28]

The etching method according to any one of [E1] to [E24], further including a step (f) of forming a protective film on the sidewall of the recess formed in the first film corresponding to the openings, in which the step (b) is performed at the same time as or after the step (f).

### [E29]

An etching method including:
a step (a) of providing a substrate, the substrate including a first film and a second film having openings on the first film, the first film containing a metallic element and a non-metallic element,
a step (b) of forming a protective film on a sidewall of a recess formed in the first film corresponding to the openings, and
a step (c) of etching the first film through the openings with a plasma generated from a processing gas including a halogen-containing gas at the same time as or after the step (b).

According to the etching method [E29], in the step (c), the etching of the sidewall of the recess of the first film is suppressed by the protective film. Therefore, according to the etching method [E29], the first film can be etched while suppressing a shape abnormality.

### [E30]

In the etching method according to [E29], the step (b) includes: a step (i) of forming a precursor layer on the sidewall of the recess, and a step (ii) of modifying the precursor layer.

### [E31]

In the etching method according to [E30], in the step (i), a plasma is generated.

### [E32]

In the etching method according to [E30] or [E31], the step (c) is performed at the same time as the step (ii).

### [E33]

In the etching method according to [E30] or [E31], the step (c) is performed after the step (ii).

### [E34]

In the etching method according to any one of [E30] to [E33], the chemical species used in the step (ii) are the same as the etchant in the plasma in the step (c).

### [E35]

In the etching method according to any one of [E30] to [E33], the chemical species used in the step (ii) are different from the etchant in the plasma in the step (c).

### [E36]

In the etching method according to any one of [E30] to [E35], in the step (b), a gas introduction port to which a modification gas for modifying the precursor layer is supplied is different from a gas introduction port to which the precursor gas for forming the precursor layer is supplied.

### [E37]

In the etching method according to any one of [E29] to [E36], the chamber in which the step (c) is performed is different from the chamber in which the step (b) is performed.

### [E38]

In the etching method according to any one of [E29] to [E37], after the step (c), a thickness of the protective film is 25% or less of the dimension of the recess.

### [E39]

In the etching method according to any one of [E29] to [E38], the first film contains at least one of tungsten, titanium, and molybdenum, as the metallic element.

### [E40]

In the etching method according to any one of [E29] to [E39], the first film contains at least one of silicon, carbon, nitrogen, oxygen, and hydrogen, as the non-metallic element.

### [E41]

In the etching method according to [E40], the first film contains tungsten silicide.

### [E42]

In the etching method according to any one of [E29] to [E41], in the step (c), a temperature of the substrate support for supporting the substrate is 60° C. or higher.

### [E43]

In the etching method according to any one of [E29] to [E42],
the second film includes a plurality of first openings arranged at a first pitch and having a first dimension, and a plurality of second openings arranged at a second pitch and having a second dimension, and
the second pitch is different from the first pitch and the second dimension is different from the first dimension.

### [E44]

In the etching method according to any one of [E29] to [E43], after the step (c), an aspect ratio of the recess is 5 or more.

### [E45]

The etching method according to any one of [E29] to [E44], further including:
before the step (a) or after the step (c), a step (d) of cleaning a chamber in which the plasma is generated.

### [E46]

The etching method according to any one of [E29] to [E45], further including:
before the step (a), a step (e) of pre-coating an inner wall of the chamber in which the plasma is generated.

### [E47]

In the etching method according to any one of [E29] to [E46], the step (a) to the step (c) are performed in-situ.

### [E48]

A plasma processing apparatus including:
a chamber,
a substrate support for supporting a substrate in the chamber, the substrate including a first film and a second film having openings on the first film, the first film containing a metallic element and a non-metallic element,
a gas supply configured to supply a processing gas into the chamber, the processing gas including a halogen-containing gas,
a plasma generator configured to generate a plasma from the processing gas in the chamber, and
a controller, in which
the controller is configured to control the gas supply and the plasma generator so that a protective film is formed on a sidewall of a recess formed in the first film corresponding to the openings and the first film is etched through the openings by the plasma at the same time as or after the protective film is formed.

### [E49]

In the etching method according to any one of [E39] to [E47], the second film is a mask.

### [E50]

In the etching method according to any one of [E30] to [E46] and [E37] to [E47] that cite [E30], at least one of a period for supplying the precursor gas in the step (i), a period for supplying the modification gas in the step (ii), and a period for supplying the processing gas in the step (c) is changed according to a depth of the recess.

### [E51]

In the etching method according to any one of [E5] to [E13], a total flow rate of the third processing gas is larger than a total flow rate of the first processing gas.

From the foregoing, it will be appreciated that various embodiments of the present disclosure have been described herein for purposes of illustration, and that various modifications may be made without departing from the scope and spirit of the present disclosure. Therefore, the various embodiments disclosed herein are not intended to be limiting, with the true scope and spirit being indicated by the following claims.

1. An etching method comprising:
step (a) providing a substrate, the substrate including a first film and a second film having an opening on the first film, the first film containing a metallic element and a non-metallic element; and
step (b) etching the first film through the opening of the second film, wherein
step (b) includes:
step (i) etching the first film through the opening of the second film with a first plasma generated from a first processing gas by supplying a pulse of a radio-frequency power, the first processing gas including a halogen-containing gas,
step (ii) modifying a sidewall of a recess formed in step (i) with a second plasma generated from a second processing gas, and
step (iii) repeating step (i) and step (ii).

2. The etching method according to claim 1, wherein
step (i) further includes supplying a continuous wave of a bias power to a substrate support for supporting the substrate.

3. The etching method according to claim 1, wherein
step (i) further includes supplying a pulse of a bias power to a substrate support for supporting the substrate, and
the pulse of the radio-frequency power and the pulse of the bias power are synchronized.

4. The etching method according to claim 1, wherein
step (i) includes supplying a pulse of a bias power to a substrate support for supporting the substrate, and
the pulse of the radio-frequency power and the pulse of the bias power have a phase shift.

5. An etching method comprising:
step (a) providing a substrate, the substrate including a first film, a second film having an opening on the first film, and a third film below the first film, the first film containing a metallic element and a non-metallic element;
step (b) etching the first film through the opening of the second film; and
step (c) further etching the first film after the step (b), wherein
step (b) includes:
step (i) etching the first film through the opening of the second film with a first plasma generated from a first processing gas that includes a halogen-containing gas,
step (ii) modifying a sidewall of a recess formed in the (i) with a second plasma generated from a second processing gas, and
step (iii) repeating step (i) and step (ii),
step (c) includes step (iv) etching the first film and the third film through the opening of the second film with a third plasma generated from a third processing gas that includes a halogen-containing gas, and
at a lower portion of the first film adjacent to an interface between the first film and the third film, a dimension of the recess formed with the third plasma is smaller than a dimension of a recess formed when the first plasma is used instead of the third plasma.

6. The etching method according to claim 5, wherein
step (i) includes supplying a first bias power to a substrate support for supporting the substrate, and
in step (iv), a second bias power is supplied to the substrate support for supporting the substrate, and energy per unit time of the second bias power is larger than energy per unit time of the first bias power.

7. The etching method according to claim 6, wherein
the first bias power is a first pulse,
the second bias power is a second pulse, and
a product of a duty cycle and an amplitude of the second pulse is larger than a product of a duty cycle and an amplitude of the first pulse.

8. The etching method according to claim 5, wherein
the third processing gas includes a reaction-promoting gas that increases an etching rate of the third film with the third plasma.

9. The etching method according to claim 8, wherein
the reaction-promoting gas includes at least one of a hydrogen-containing gas or a CₓH_{y}F_{z} gas, where x is an integer of 1 or more, and y and z are integers of 0 or more.

10. The etching method according to claim 5, wherein
step (c) does not include modifying the sidewall of the recess with a fourth plasma generated from a fourth processing gas.

11. The etching method according to claim 5, wherein
step (c) further includes step (v) modifying the sidewall of the recess with a fourth plasma generated from a fourth processing gas,
in step (ii), the second processing gas includes an oxygen-containing gas,
in step (v), the fourth processing gas includes an oxygen-containing gas, and
a partial pressure of the oxygen-containing gas in the fourth processing gas is lower than a partial pressure of the oxygen-containing gas in the second processing gas.

12. The etching method according to claim 5, wherein
step (i) includes supplying a first radio-frequency power for generating the first plasma,
step (iv) includes supplying a second radio-frequency power for generating the third plasma, and
energy per unit time of the second radio-frequency power is smaller than energy per unit time of the first radio-frequency power.

13. The etching method according to claim 5, wherein
in step (i), the first plasma is generated under a first pressure,
in step (iv), the third plasma is generated under a second pressure, and
the second pressure is lower than the first pressure.

14. The etching method according to claim 5, wherein
a total flow rate of the third processing gas is higher than a total flow rate of the first processing gas.

15. The etching method according to claim 5, wherein
the third film is an etching stop layer.

16. The etching method according to claim 1, wherein
the first film contains at least one transition metallic element selected from the group consisting of tungsten, titanium, molybdenum, hafnium, zirconium, and ruthenium, as the metallic element.

17. The etching method according to claim 1, wherein
the first film contains at least one of silicon, carbon, nitrogen, oxygen, hydrogen, boron, or phosphorus, as the non-metallic element.

18. The etching method according to claim 17, wherein
the first film contains at least one tungsten compound selected from the group consisting of tungsten silicide, tungsten silicon nitride, tungsten silicon boron, and tungsten silicon carbon.

19. The etching method according to claim 1, wherein
the second film is a mask.

20. The etching method according to claim 1, wherein
in step (i), a temperature of the substrate support for supporting the substrate is 60° C. or higher.

21. The etching method according to claim 1, wherein
the opening of the second film includes a plurality of first openings arranged at a first pitch and having a first dimension, and a plurality of second openings arranged at a second pitch and having a second dimension, and
the second pitch is different from the first pitch and the second dimension is different from the first dimension.

22. The etching method according to claim 1, wherein
after step (iii), an aspect ratio of the recess is 5 or more.

23. The etching method according to claim 1, further comprising:
step (d) cleaning, before step (a) or after step (b), a chamber in which the first plasma is generated.

24. The etching method according to claim 1, further comprising:
step (e) pre-coating, before step (a), an inner wall of a chamber in which the first plasma is generated.

25. The etching method according to claim 1, wherein
step (a) and step (b) are performed in-situ.

26. A plasma processing apparatus comprising:
a chamber;
a substrate support for supporting a substrate in the chamber, the substrate including a first film and a second film having an opening on the first film, the first film containing a metallic element and a non-metallic element;
a gas supply configured to supply a first processing gas and a second processing gas into the chamber, the first processing gas including a halogen-containing gas;
a plasma generator configured to generate a first plasma from the first processing gas in the chamber and a second plasma from the second processing gas in the chamber; and
a controller configured to control the gas supply and the plasma generator to perform:
step (i) etching the first film through the opening of the second film with the first plasma by supplying a pulse of a radio-frequency power,
step (ii) modifying a sidewall of a recess formed in the step (i) with the second plasma, and
step (iii) repeating step (i) and step (ii).

27. A plasma processing apparatus comprising:
a chamber;
a substrate support for supporting a substrate in the chamber, the substrate including a first film, a second film having an opening on the first film, and a third film below the first film, the first film containing a metallic element and a non-metallic element;
a gas supply configured to supply a first processing gas, a second processing gas, and a third processing gas into the chamber, the first processing gas including a halogen-containing gas, the third processing gas including a halogen-containing gas;
a plasma generator configured to generate a first plasma from the first processing gas in the chamber, a second plasma from the second processing gas in the chamber, and a third plasma from the third processing gas in the chamber; and
a controller configured to control the gas supply and the plasma generator to perform:
step (i) etching the first film through the opening of the second film with the first plasma,
step (ii) modifying a sidewall of a recess formed in the (i) with the second plasma,
step (iii) repeating step (i) and step (ii), and
step (iv) etching the first film and the third film through the opening of the second film with the third plasma, after step (iii), wherein
the controller is configured to control the gas supply and the plasma generator so that at a lower portion of the first film adjacent to an interface between the first film and the third film, a dimension of the recess formed with the third plasma is smaller than a dimension of a recess formed when the first plasma is used instead of the third plasma.
